(19) United States
(12) Patent Application Publication
(10) Pub. No.: US 2024/0347336 A1
(43) Pub. Date: Oct. 17, 2024

(54) COATING COMPONENTS FOR SEMICONDUCTOR PROCESSING WITH FLUORINE-CONTAINING MATERIALS

(71) Applicant: Applied Materials, Inc., Santa Clara, CA (US)

(72) Inventors: Nitin Deepak, Thane (IN); Ryan Sheil, Santa Cruz, CA (US); Jennifer Y. Sun, Fremont, CA (US); Zhijun Jiang, San Jose, CA (US); Katherine Woo, Santa Clara, CA (US)

(73) Assignee: Applied Materials, Inc., Santa Clara, CA (US)

(21) Appl. No.: 18/135,434

(22) Filed: Apr. 17, 2023

(51) Int. Cl. H01L 21/02; C23C 16/08; H01J 37/32

(52) U.S. Cl. CPC H01L 21/02178; C23C 16/08; H01J 37/32091; H01J 37/321; H01L 21/0214; H01L 21/02186; H01L 21/02189; H01L 21/02192; H01J 2237/332

(57) ABSTRACT

Exemplary processing methods may include providing a component for semiconductor processing to a processing region of a processing chamber. The methods may include providing one or more deposition precursors to the processing region. The one or more deposition precursors may include a metal-containing precursor and a fluorine-containing precursor. The methods may include depositing a layer of material on the component for semiconductor processing in the processing region. The layer of material comprises a metal-and-fluorine-containing material.

### TECHNICAL FIELD

The present technology relates to coating processes and semiconductor chamber components. More specifically, the present technology relates to modified components and component materials.

### BACKGROUND

Integrated circuits are made possible by processes which produce intricately patterned material layers on substrate surfaces. Producing patterned material on a substrate requires controlled methods of formation and removal of exposed material. Deposition and removal operations may include producing a remote plasma or a local plasma in a processing region of a semiconductor processing chamber, for example, between a showerhead or gas distributor and a substrate support. Components of the semiconductor processing chamber may be exposed to plasma species during processing. Where the components exposed to corrosive species on a repeated basis, degradation of the components and contamination of substrates being processed may occur. Accordingly, a top coating may be provided to protect the underlying component from corrosion and/or erosion. However, applying the top coating may require the use of volatile precursors or may be time intensive processes.

Thus, there is a need for improved systems and system components that can be used to produce high quality devices and structures. These and other needs are addressed by the present technology.

### SUMMARY

Exemplary processing methods may include providing a component for semiconductor processing to a processing region of a processing chamber. The methods may include providing one or more deposition precursors to the processing region. The one or more deposition precursors may include a metal-containing precursor and a fluorine-containing precursor. The methods may include depositing a layer of material on the component for semiconductor processing in the processing region. The layer of material comprises a metal-and-fluorine-containing material.

In some embodiments, the component for semiconductor processing may be or include a ceramic-containing material. The ceramic-containing material may be or include aluminum oxide (Al₂O₃), aluminum oxyfluoride (AlOₓF_{y}), yttrium oxide (Y₂O₃), yttrium oxyfluoride (YOₓF_{y}), magnesium oxide (MgO), magnesium oxyfluoride (MgOₓF_{y}), titanium oxide (TiO₂), titanium oxyfluoride (TiOₓF_{y}), aluminum nitride (AlN), aluminum oxynitride (AlOₓN_{y}), silicon nitride (Si₃N₄), or silicon oxynitride (SiOₓN_{y}). The metal-containing precursor may include a hexafluoroacetylacetone compound. The metal-containing precursor may include aluminum, calcium, erbium, lanthanum, magnesium, scandium, titanium, yttrium, or zirconium. The fluorine-containing precursor may be or include hydrogen fluoride (HF), ammonium fluoride (NH4F) or ammonium bifluoride ([NH₄]F·HF). The layer of material may be aluminum fluoride (AlF₃), aluminum oxyfluoride (AlOₓF_{y}), calcium fluoride (CaF₂), calcium oxyfluoride (CaOₓF_{y}), yttrium fluoride (YF₃), yttrium oxyfluoride (YOₓF_{y}), zirconium fluoride (ZrF₄), zirconium oxyfluoride (ZrOₓF_{y}), scandium fluoride (ScF₃), or scandium oxyfluoride (ScOₓF_{y}). The one or more deposition precursors further include an oxygen-containing precursor. The layer of material may be a metal-fluorine-and-oxygen-containing material. The oxygen-containing precursor comprises steam (H₂O), molecular oxygen (O₂), ozone (O₃), nitrous oxide (N₂O), hydrogen peroxide (H₂O₂), an oxygen-containing plasma, or an alcohol-based plasma. The layer of material further include nitrogen. The methods may include generating plasma effluents of the one or more deposition precursors. The methods may include, subsequent to depositing the layer of material, annealing the component for semiconductor processing. The component for semiconductor processing may be annealed in a pressure-controlled oxygen-containing environment, inert environment, or active gas environment. A temperature within the processing region may be maintained at less than or about 2,000° C. The component for semiconductor processing may be or include a lid, a nozzle, a face plate, a gas distribution plate, a heater, a screw, a substrate support, a support platen, a liner, an edge ring, a process kit ring, or a lift pin.

Some embodiments of the present technology encompass processing methods. The methods may include providing a component for semiconductor processing to a processing region of a processing chamber. The methods may include depositing a layer of material on the component for semiconductor processing in the processing region. The layer of material may be or include a metal-and-fluorine-containing material. Depositing the layer of material may include exposing the component for semiconductor processing to plasma effluents of a first precursor, purging the processing region, and exposing the component for semiconductor processing to plasma effluents of a second precursor. The layer of material may include reaction products of the plasma effluents of the first precursor and the plasma effluents of the second precursor. A temperature within the processing chamber may be maintained at greater than or about 400° C.

In some embodiments, the component for semiconductor processing may be or include aluminum oxide (Al₂O₃), aluminum oxyfluoride (AlOₓF_{y}), yttrium oxide (Y₂O₃), yttrium oxyfluoride (YOₓF_{y}), magnesium oxide (MgO), magnesium oxyfluoride (MgOₓF_{y}), titanium oxide (TiO₂), titanium oxyfluoride (TiOₓF_{y}), aluminum nitride (AlN), aluminum oxynitride (AlOₓN_{y}), silicon nitride (Si₃N₄), or silicon oxynitride (SiOₓN_{y}). The layer of material may be or include a metal-fluorine-and-oxygen-containing material.

Some embodiments of the present technology encompass components for semiconductor processing. The components may include a ceramic component for semiconductor processing. The components may include a layer of metal-and-fluorine-containing material on the component for semiconductor processing. The layer of metal-and-fluorine-containing material may be formed on the ceramic component for semiconductor processing using a fluorine-containing precursor comprising ammonium fluoride (NH4F) or ammonium bifluoride ([NH₄]F·HF), a metal-containing precursor comprising a hexafluoroacetylacetone compound, or both. A temperature while forming the layer of metal-and-fluorine-containing material on the component for semiconductor processing may be maintained at greater than or about 400° C.

In some embodiments, the component for semiconductor processing may be or include a lid, a nozzle, a face plate, a gas distribution plate, a heater, a screw, a substrate support, a support platen, a liner, an edge ring, a process kit ring, or a lift pin.

Such technology may provide numerous benefits over conventional techniques. For example, the methods may provide a coated component for semiconductor processing exhibiting improved compatibility with plasma processing applications. For example, a component may be chemically reduced to remove a passivation layer on the grains of the component. In this way, a layer of material may be a coated directly onto a component, for example, by atomic layer deposition. Additionally, specific precursors and/or operating conditions may be utilized to ease processing for forming a corrosion-resistant and/or erosion-resistant layer of material on the component. The precursors and/or operating conditions may also increase throughput and reduce queue times for coating components. As such, the coated component for semiconductor processing may exhibit improved thermal, mechanical, and/or chemical properties, including in halogen plasma environments at which semiconductor processing operations are undertaken. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic view of an exemplary processing chamber according to some embodiments of the present technology.

FIG. 2 shows exemplary operations in a deposition method according to some embodiments of the present technology.

FIG. 3 show schematic views of a component during operations in a deposition method according to some embodiments of the present technology.

FIG. 4 show schematic views of an exemplary processing chamber component formed the method according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As part of semiconductor processing technology, deposition and removal operations may include producing a remote plasma or a local plasma in a processing region of a semiconductor processing chamber, for example, between a showerhead or gas distributor and a substrate support. Components of the semiconductor processing chamber may be or include a ceramic material. In order to protect the ceramic material during operations using plasma, a top coating may be provided to protecting the underlying material. The top coating may be a combination of materials, such as metal fluorides. However, forming the metal fluorides may require corrosive fluorine-containing precursors as well as slow deposition operations that require long processing times to form the layers of material on the components.

Conventional technologies have approached depositing metal fluorides using corrosive fluorine-containing precursors. These corrosive precursors require careful handling during processing. Additionally, conventional technologies have deposited metal fluorides using deposition techniques that require long periods of time, resulting in reduced throughput. . . . The present technology may overcome these limitations by implementing improved deposition methods to remove a native passivation layer from the component, which may permit deposition of materials onto the component, for example, by atomic layer deposition. In addition, by utilizing specific fluorine-containing precursors that are less corrosive than conventional fluorine-containing precursors, corrosivity concerns during processing may be relaxed. Further, by operating the deposition processing at elevated temperatures compared to conventional processes, the material may be formed quicker. By depositing the material at a faster rate than conventional processes, throughput may be increased and queue times may be reduced. This may enable preparation of coated components for semiconductor processing for application in, for example, plasma processing chamber components with tailored thermal, mechanical, and chemical properties at conditions used for semiconductor processing. As a result, the coated components for semiconductor processing may be implemented in semiconductor processing chambers that are exposed to plasma operations.

After describing general aspects of a chamber according to embodiments of the present technology in which plasma processing may be performed, specific methodology and component configurations may be discussed. It is to be understood that the present technology is not intended to be limited to the specific films and processing discussed, as the techniques described may be used to improve a number of film formation processes, and may be applicable to a variety of processing chambers and operations.

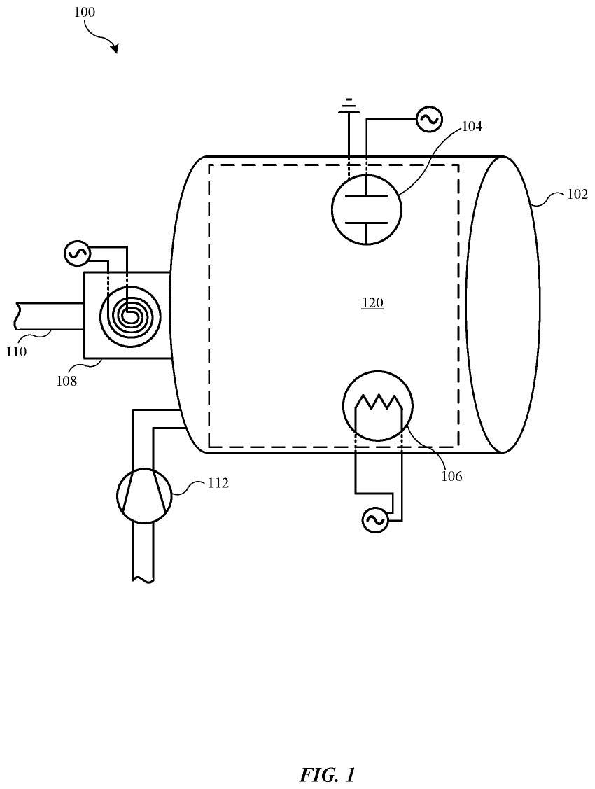

FIG. 1 shows a schematic view of an exemplary processing chamber 100 according to some embodiments of the present technology. The figure may illustrate an overview of a system incorporating one or more aspects of the present technology, and/or which may perform one or more operations according to embodiments of the present technology. Additional details of chamber 100 or methods performed may be described further below. Chamber 100 may be utilized to form coated components for semiconductor processing according to some embodiments of the present technology, although it is to be understood that the methods may similarly be performed in any chamber within which film formation may occur. The processing chamber 100 may include a chamber body 102, a plasma system 104 inside the chamber body 102, a temperature control system 106, and a remote plasma system 108 coupled with the chamber body 102 and configured to provide plasma effluents to a processing region 120 of the chamber body 102.

A component for semiconductor processing may be provided to the processing region 120 through a material feedthrough, such as a port or conduit, which may be sealed for processing using a slit valve, gate valve, or door. Precursors, as described below, may be provided to the chamber 100 through a gas supply system 110. While FIG. 1 illustrates a single inlet for the gas supply system 110, the chamber 100 may include multiple gas inlets coupled with the chamber body 102 at one or more locations. For example, a plasma precursor may be introduced to the chamber body through the remote plasma system 108, while a second gas inlet may provide gases for which plasma dissociation would negatively impact the deposition process. Gases may be removed from the chamber body 102 by a gas removal system 112. The gas removal system 112 may include a vacuum system, configured to facilitate reduced pressure operation during deposition processes and to evacuate the chamber to remove process effluents and unreacted process gases. Measurement and control systems may be coupled with the chamber to measure operating pressure in one or more places, such as in the gas supply system 110, the gas removal system 112, or in the processing region 120. In another example, the temperature control system 106 may include temperature sensors and a heating element configured to provide heat to the processing region 120 or to remove heat from the processing region 120. In this way, the chamber 100 may implement controlled deposition and removal processes, such as plasma etching and removal, and atomic layer deposition.

As part of implementing plasma processing of components for semiconductor processing in the chamber 100, in accordance with the methods described below, the plasma system 104 may be configured to form a plasma within the processing region 120. The plasma system 104 may be or include an indirect plasma system, such as an RF capacitively-coupled plasma, configured to form a plasma within the processing region 120 by generating sufficiently strong electric fields internal to the chamber body 102. In some embodiments, the plasma system 104 may be or include a direct plasma system, such that one or more electrode surfaces are disposed within the chamber body. In this way, the processing region 120 may be defined between a live electrode and a reference ground electrode of the plasma system 104. The plasma system 104 may also include control systems and power supply systems, such as impedance matching circuits and 13.56 MHz RF power supplies.

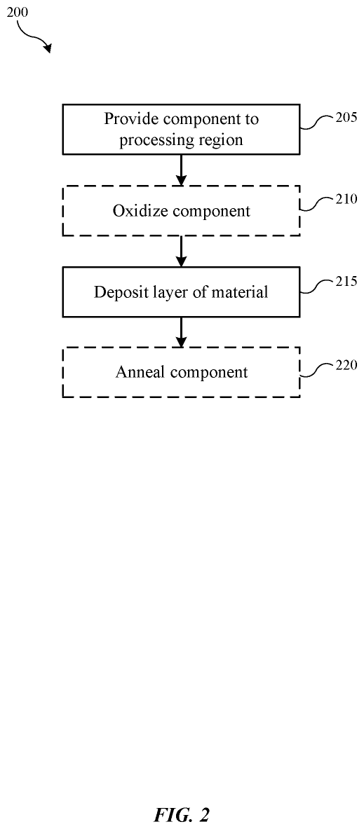

Similarly, the remote plasma system 108 may be or include a direct plasma system or an indirect plasma system, such as an inductively coupled RF plasma system or a capacitively coupled RF plasma system, which may be configured to decompose a precursor into plasma effluents that can be provided to the processing region 120. For example, the gas supply system 110 may include a quartz inlet tube coupled with a feedthrough to the chamber body 102. In such an arrangement, the remote plasma system 108 may be or include an ICP or a CCP system disposed external to the quartz inlet tube and configured to form a plasma within the quartz inlet tube. As further described in reference to FIG. 2, the precursor may include an inert carrier gas and a reaction precursor that may be or include a vapor or a gas. In this way, the remote plasma system 108 may form an indirect plasma in the precursor and may decompose the precursor. The decomposed precursor may be or include plasma effluents, which may be or include carrier gas, unreacted precursor, and plasma generated species. The plasma generated species may serve as reactants in a chemical reaction mediated deposition process, such as conformal deposition processes including, but not limited to, chemical vapor deposition (CVD) and atomic layer deposition (ALD), and direct line of sight deposition processes including, but not limited to, physical vapor deposition (PVD), ion beam (IB) deposition, electron beam (EB) deposition, or electron beam ion-assisted deposition (EB-IAD). As with the plasma system 104, remote plasma system 108 may also include control systems and power supply systems, such as impedance matching circuits and 13.56 MHz RF power supplies.

The temperature control system 106 may be configured to maintain an internal temperature in the processing region in accordance with a processing method. For example, as part of atomic layer deposition, a deposition substrate, such as a component for semiconductor processing, may be heated to a reaction temperature at which a particular reaction product is favored. In an illustrative example, a surface reaction that forms a layer of material on the deposition substrate may be thermodynamically favored at an elevated temperature. As such, the temperature control system 106 may provide heat to the processing region. In some embodiments, the temperature control system may be at least partially integrated into the plasma system 104. For example, an electrode of the plasma system 104 may incorporate heating and/or cooling elements, permitting the plasma system to operate within a range of operating temperatures.

In some embodiments, the chamber 100 may be configured to prepare coated components for semiconductor processing for which the components are coated with one or more layers of material. As described in reference to methods and systems, below, the chamber 100 may permit the preparation of improved coated ceramic-containing components for semiconductor processing, which may be incorporated into semiconductor processing systems. Such components may exhibit improved thermal, mechanical, and/or chemical properties at processing conditions that are characteristic of plasma deposition and removal operations as part of semiconductor processing.

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

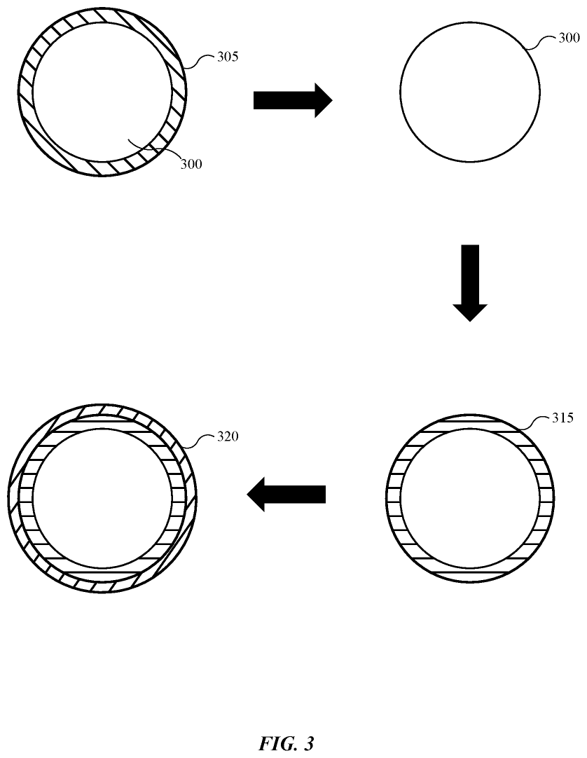

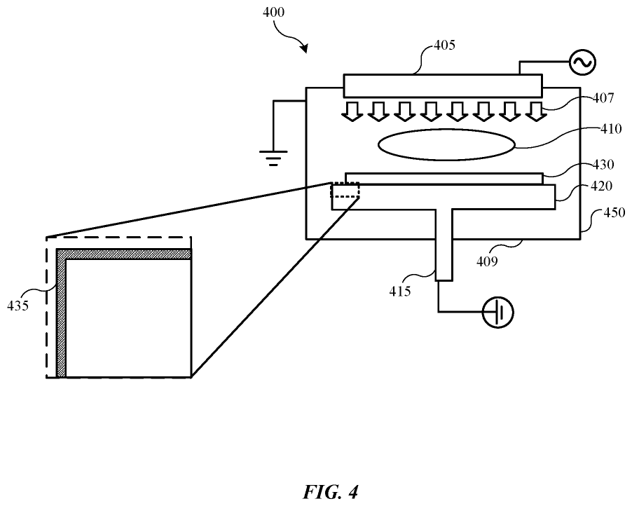

Method 200 describes operations shown schematically in FIG. 3, the illustrations of which will be described in conjunction with the operations of method 200. FIG. 4 illustrates an exemplary semiconductor processing system incorporating materials produced according to some embodiments of the method 200. It is to be understood that FIGS. 3-4 illustrate only partial schematic views, and a processing system may include subsystems as illustrated in the figures, as well as alternative subsystems, of any size or configuration that may still benefit from aspects of the present technology.

FIG. 3 show schematic views of a component for semiconductor processing 300 during operations of the method 200 according to some embodiments of the present technology. In some embodiments, the method 200 may include one or more operations preceding those illustrated in FIG. 2. For example, one or more processes may be implemented to form the component for semiconductor processing 300 from a feedstock material. For example, the component for semiconductor processing 300 may be formed by chemically converting an oxide to a nitride, and may be cleaned, for example, by baking, etching, or degreasing. Examples of nitride synthesis may include, but are not limited to, carbo-thermal nitridization and/or direct nitridization. Furthermore, the component for semiconductor processing 300 may be introduced into a processing chamber, such as the chamber 100, bearing a passivation layer 305. For example, the component for semiconductor processing 300 may be or include aluminum nitride, which, through exposure to oxygen during cleaning or through exposure to air at ambient conditions, may develop an oxide passivation layer.

Method 200 may include additional operations prior to initiation of the listed operations. For example, as illustrated in FIG. 3, method 200 may include removing a passivation layer 305, such as a native oxide or surface oxide, prior to coating the component.

Removing the passivation layer may include providing hydrogen to the processing region of the chamber. Hydrogen may permit a hydrogen plasma, a hydrogen-rich plasma, or a trace-hydrogen plasma to be formed in the processing region, as an approach to chemically reducing the passivation layer 305. The hydrogen may be provided to the processing region of the chamber with an inert carrier gas. In plasma systems, inert carrier gases, also referred to as “forming gases”, facilitate plasma ignition and control of plasma conditions. For example, providing the hydrogen with a given inert gas fraction may permit the plasma to operate under controlled plasma conditions, such as ionization fraction, ion temperature, or electron temperature. Subsequent introducing hydrogen into the processing region, the method 200 may include striking a plasma in the processing region. The plasma may be or include a hydrogen plasma, and as such it may include energetic plasma species, such as hydrogen ions, hydrogen radicals, or metastable diatomic hydrogen. The hydrogen plasma may be formed in the processing region while the component for semiconductor processing 300 is positioned in the processing region. The plasma treatment may be performed based on hydrogen supplied with a carrier gas, such as argon or helium, for generating the plasma, and the hydrogen may constitute a percentage material in the gas mixture.

During method 200, the component for semiconductor processing 300 may be positioned in the processing region. At operation 205, method 200 may include delivering the component for semiconductor processing 300 to the processing region of the processing chamber, such as processing chamber 100 described above, or other chambers that may include components as described above. The component for semiconductor processing 300 may include a plurality of individual particles. The particles making up the component for semiconductor processing 300 may be any type of material and may be a ceramic-containing material in embodiments. For example, the particles of component for semiconductor processing 300 may be or include, but are not limited to, aluminum oxide (Al₂O₃), aluminum oxyfluoride (AlOₓF_{y}), yttrium oxide (Y₂O₃), yttrium oxyfluoride (YOₓF_{y}), magnesium oxide (MgO), magnesium oxyfluoride (MgOₓF_{y}), titanium oxide (TiO₂), titanium oxyfluoride (TiOₓF_{y}), aluminum nitride (AlN), aluminum oxynitride (AlOₓN_{y}), silicon nitride (Si₃N₄), or silicon oxynitride (SiOₓN_{y}), or any combination thereof.

In some embodiments, method 200 may optionally include oxidizing the component for semiconductor processing 300 at optional operation 210. Optional operation 210 may include introducing oxygen into the processing region of the chamber. Introducing oxygen into the processing region as part of plasma enhanced deposition may permit the formation of a controlled oxide layer on the component for semiconductor processing 300. In contrast to the passivation layer 305, the controlled oxide layer may be formed under controlled conditions, such as in an oxygen plasma in the processing region, such that an oxide layer may be formed on the component for semiconductor processing 300 with a characteristic and uniform thickness. Additionally or alternatively, optional operation 210 may include thermal oxidation of the component for semiconductor processing 300 subsequent removal of the passivation film 305. A surface oxide layer may impart improved control of thermal, mechanical, and/or chemical properties in a component for semiconductor processing 300, for example, by acting as a diffusion barrier. In this way, it may be advantageous to reduce the component for semiconductor processing 300 to remove the passivation layer 305, and subsequently to oxidize the component for semiconductor processing 300 under controlled conditions to reform an oxide layer.

Subsequent oxidizing the component for semiconductor processing 300 at optional operation 210, method 200 may include forming a layer of material 315 on the component for semiconductor processing 300 at operation 215. In some embodiments, forming the layer of material 315 on the component for semiconductor processing 300 may include undertaking operations of an atomic layer deposition (ALD) process, whereby the component for semiconductor processing 300 may be uniformly coated. However, as previously discussed, forming the layer of material 315 may be performed using a variety of deposition methods. For example, operation 215 may include introducing plasma effluents to the processing region.

Plasma effluents may be or include plasma generated species that are formed by a remote plasma system, such as remote plasma system 108 of FIG. 1, in communication with the processing region. Introducing the plasma effluents may include introducing a carrier gas including the plasma effluents. In this way, introducing the plasma effluents into the processing region may expose the component for semiconductor processing 300 to plasma effluents of one or more precursors that have been subjected to plasma decomposition. Plasma effluents, therefore, may be or include ions, activated radicals, metastable species, and other decomposition products, and may be characterized by average energy distribution lower than that of a direct plasma system. Exposing the component for semiconductor processing 300 to the plasma effluents may, in turn, result in the formation of an adsorbed monolayer of plasma effluents on the surface of the component for semiconductor processing 300 that serves as a precursor to the formation of the layer of material 315.

In a second operation of atomic layer deposition, the plasma effluents of the first precursor may be removed from the processing region by purging the processing region of gas, while retaining the component for semiconductor processing 300 bearing the adsorbed monolayer. Purging the processing region may be implemented using a gas removal system, such as the gas removal system 112 of FIG. 1. Subsequent purging, a second precursor may be decomposed into second plasma effluents, such that the component for semiconductor processing 300 is exposed to the second plasma effluents. The second precursor may be chosen such that it decomposes into plasma generates species that react with the monolayer adsorbed on the component for semiconductor processing 300 to form the layer of material 315. Subsequent forming the layer of material 315, the unreacted plasma effluents and reaction byproducts may be removed by the gas removal system.

In some embodiments, the first and second precursors may be selected such that the layer of material 315 may be or include a corrosion-resistant and/or erosion-resistant additive to improve the mechanical properties of the component for semiconductor processing 300. For example, the layer of material 315 may be a metal-and-fluorine-containing material. In this way, one precursor may be or include a metal-containing precursor and the other precursor may be or include a fluorine-containing precursor. The metal may be or include, for example, a rare earth element or a transition metal. For example, one of the precursors may include the metal, such as aluminum, calcium, erbium, lanthanum, magnesium, scandium, titanium, yttrium, or zirconium.

In embodiments, the metal-containing precursor may include a hexafluoroacetylacetone compound. For example, the metal may be in solution with hexafluoroacetylacetone (hfac). For example, the metal-containing precursor may be or include, but is not limited to, Mg(hfac)₂, or Magnesium(hfac)(dmg)H₂O, Al(hfac)₃, Y(hfac)₃. The other precursor may include fluorine, and may be, for example, hydrogen fluoride (HF), ammonium fluoride (NH₄F) or ammonium bifluoride ([NH₄]F·HF). While other fluorine-containing precursors are contemplated, such as molecular fluorine (F₂), nitrogen trifluoride (NF₃), and HF-pyridine (HF·C₅H₅N), these precursors may be more difficult to handle due to their corrosive nature. Accordingly, hydrogen fluoride (HF), ammonium fluoride (NH₄F) or ammonium bifluoride ([NH₄]F·HF) may permit easier processing while still providing desired formation and material characteristics. Further, one or more co-reactants may be provided with either the metal-containing precursor and/or the fluorine-containing precursor. The co-reactant may be or include, but is not limited to, an oxygen-containing precursor such as water or steam (H₂O), molecular oxygen (O₂), ozone (O₃), nitrous oxide (N₂O), hydrogen peroxide (H₂O₂), an oxygen-containing plasma, or an alcohol-based plasma or any other co-reactant useful in semiconductor processing such as hydrogen fluoride (HF), F₂, or NH₄F. Further, a nitrogen-containing precursor may be provided in embodiments where the layer of material 315 is to include nitrogen. Depending on the precursors utilized during the deposition, the layer of material 315 may include, for example, aluminum fluoride (AlF₃), aluminum oxyfluoride (AlOₓF_{y}), calcium fluoride (CaF₂), calcium oxyfluoride (CaOₓF_{y}), yttrium fluoride (YF₃), yttrium oxyfluoride (YOₓF_{y}), zirconium fluoride (ZrF₄), zirconium oxyfluoride (ZrOₓF_{y}), scandium fluoride (ScF₃), or scandium oxyfluoride (ScOₓF_{y}), although any other metal-and-fluorine-containing material is contemplated, including a layer of material 315 including multiple metals.

In embodiments, additional layers of material may be formed on the component for semiconductor processing 300, or the layer of material 315 may include additional elements. The additional layers of material or the layer of material 315 may include multiple different materials, including oxide or nitride materials, in addition to the metal-and-fluorine-containing material. Other precursors, aside from the metal-containing precursor and the fluorine-containing precursor, may include oxygen or nitrogen source and may be, for example, steam (H₂O), hydrogen peroxide (H₂O₂), oxygen (O₂), oxygen-based plasma, ozone (O₃), nitrous oxide (N₂O), molecular nitrogen (N₂), ammonia (NH₃), hydrazine (N₂H₄), or nitrogen-based plasma. Based on the precursors used, the additional layers of material may be an oxide, a nitride, or an oxynitride. For example, additional layers of material may be or include, but is not limited to, aluminum oxide (Al₂O₃), yttrium oxide (Y₂O₃), magnesium oxide (MgO), titanium oxide (TiO₂), erbium oxide (Er₂O₃), lanthanum oxide (La₂O₃), scandium oxide (Sc₂O₃), zirconium oxide (ZrO₂), aluminum nitride (AlN), silicon nitride (SiN), tantalum nitride (TaN), titanium nitride (TIN), or zirconium nitride (ZrN).

In some embodiments, the constituent operations of the operation 215 may be repeated to deposit multiple monolayers, such that the layer of material 315 may be formed on a monolayer-by-monolayer basis, and the thickness of the layer of material 315 may be an integer multiple of the monolayer thickness and the number of repetitions of the operation 215. Furthermore, following operation 215, a second layer of material 320 may be formed overlying the layer of material 315, by repeating the operation with either the same set of first and second precursors or a different set of first and second precursors. For example, where the layer of material 315 may be or include aluminum fluoride, the second material 320 may be or include a different fluorine, such as yttrium aluminum fluoride, or another oxide, nitride, or fluoride. As such, a coated component for semiconductor processing 300 by the method 200 may include a controlled oxide layer, the layer of material 315, and one or more additional layers of different materials, such as the second layer of material 320.

A flowrate of the precursors introduced to the chamber may depend at least in part on one or more parameters of the chamber, the component for semiconductor processing 300, or the method 200. For example, the flowrate may be adjusted such that a plasma may form with a sufficient energy density or species density, such as ions, free electrons, or activated precursor, to facilitate, for example, reduction of the passivation layer 305 or deposition of the layer of material 315.

Related to the flowrate of the precursors, a pulse size of the first precursor or of the second precursor may be less than or about 75 minutes. At times greater than 75 minutes, the component for semiconductor processing 300 may be fully saturated and no longer accept the precursor to form a monolayer of material. Accordingly, the pulse size of the first precursor or of the second precursor may be less than or about 70 minutes, less than or about 65 minutes, less than or about 60 minutes, less than or about 55 minutes, less than or about 50 minutes, less than or about 45 minutes, less than or about 40 minutes, less than or about 35 minutes, less than or about 30 minutes, less than or about 25 minutes, less than or about 20 minutes, less than or about 15 minutes, less than or about 10 minutes, less than or about 5 minutes, less than or about 2 minutes, less than or about 1 minute, less than or about 50 seconds, less than or about 40 seconds, less than or about 30 seconds, less than or about 20 seconds, less than or about 10 seconds, or less.

Similarly a pulse size of the purge gas to purge the first precursor may be less than or about 120 minutes, such as less than or about 110 minutes, less than or about 100 minutes, less than or about 90 minutes, less than or about 80 minutes, less than or about 70 minutes, less than or about 65 minutes, less than or about 60 minutes, less than or about 55 minutes, less than or about 50 minutes, less than or about 45 minutes, less than or about 40 minutes, less than or about 35 minutes, less than or about 30 minutes, less than or about 25 minutes, less than or about 20 minutes, less than or about 15 minutes, less than or about 10 minutes, less than or about 5 minutes, less than or about 2 minutes, less than or about 1 minute, or less. The purge may be a longer duration than the precursor in order to ensure the precursors are fully removed from the processing region.

During method 200, such as during operation 215, a temperature within the processing chamber may be maintained at less than or about 2,000° C. While higher temperatures may be employed, depositions of the present technology may be operated at temperatures less than or about 1,750° C., such as less than or about 1,500° C., less than or about 1,250° C., less than or about 1,000° C., less than or about 900° C., less than or about 800° C., less than or about 750° C., less than or about 725° C., less than or about 700° C., less than or about 675° C., less than or about 650° C., less than or about 625° C., less than or about 600° C., less than or about 575° C., less than or about 550° C., less than or about 525° C., less than or about 500° C., less than or about 480° C., less than or about 460° C., less than or about 440° C., less than or about 420° C., less than or about 400° C., less than or about 380° C., less than or about 360° C., less than or about 340° C., less than or about 320° C., less than or about 300° C., less than or about 280° C., less than or about 260° C., less than or about 240° C., less than or about 220° C., less than or about 200° C., less than or about 180° C., less than or about 160° C., less than or about 140° C., less than or about 120° C., less than or about 100° C., less than or about 80° C., less than or about 60° C., less than or about 40° C., less than or about 20° C., or less. However, higher temperatures may increase the deposition of the material which may increase throughput. In embodiments, an ALD deposition performed at higher temperatures may make the deposition proceed more as a CVD deposition. Accordingly, the temperature within the processing chamber may be maintained at greater than or about 300° C., such as greater than or about 350° C., greater than or about 400° C., greater than or about 450° C., greater than or about 500° C., or more.

Additionally, during method 200, such as during operation 215, a pressure within the processing chamber may be maintained at less than or about 50 mTorr. Again, while higher pressures may be employed, depositions of the present technology may be operated at pressures less than or about 50 mTorr, such as less than or about 45 mTorr, less than or about 40 mTorr, less than or about 35 mTorr, less than or about 30 mTorr, less than or about 25 mTorr, less than or about 20 mTorr, less than or about 15 mTorr, less than or about 10 mTorr, less than or about 7 mTorr, less than or about 5 mTorr, less than or about 3 mTorr, less than or about 1 mTorr, or less.

The layer of material 315 may be formed to a thickness of less than or about 3000 nm, such as less than or about 2750 nm, less than or about 2500 nm, less than or about 2250 nm, less than or about 2000 nm, less than or about 1750 nm, less than or about 1500 nm, less than or about 1250 nm, less than or about 1000 nm, less than or about 750 nm, less than or about 500 nm, less than or about 250 nm, less than or about 100 nm, or less. In embodiments, depending on the application, the layer of material 315 may be formed to a much smaller thickness, such as less than or about 90 nm, less than or about 80 nm, less than or about 70 nm, less than or about 60 nm, less than or about 50 nm, less than or about 40 nm, less than or about 30 nm, less than or about 20 nm, less than or about 10 nm, less than or about 5 nm, less than or about 2 nm, less than or about 1 nm, or less.

At optional operation 220, the method 200 may include annealing the component for semiconductor processing 300. Annealing the component for semiconductor processing 300 at optional operation 220 may alter the crystallinity and/or grain size of the layer of material 315 or may further enhance the thermal, mechanical, and or chemical properties of the layer of material 315, such as the corrosion and/or erosion resistance properties as well as hardness and other microstructure characteristics. For example, the layer of material 315 may be formed as an amorphous structure, but the anneal at optional operation 220 may cause the layer of material 315 to transition to a crystalline structure. The component for semiconductor processing 300 may be annealed in an oxygen-containing environment, in an inert environment, or in an active gas environment. In embodiments, the active gas environment may include but is not limited to, for example, a fluorine-containing environment. The fluorine-containing environment may include, but is not limited to, diatomic fluorine (F2). In embodiments, the component for semiconductor processing 300 may be annealed at a temperature greater than or about 300° C., such as greater than or about 350° C., greater than or about 400° C., greater than or about 450° C., greater than or about 500° C., greater than or about 550° C., greater than or about 600° C., greater than or about 650° C., greater than or about 700° C., or more, which may be greater than the temperature at operation 215. During optional operation 220, the pressure may be controlled, and the pressure may be maintained greater than, less than, or at about atmospheric pressure.

The method 200 and its constituent operations may provide one or more improvements to plasma enhanced deposition processes for depositing materials layers onto a component for semiconductor processing such as by, for example, ALD. For example, the method 200 may provide a coated component for semiconductor processing characterized by a core shell structure, where the core may be or include a ceramic material of the component, such as aluminum nitride or any other ceramic material, with one or more shells, such as a transition metal fluoride or a rare earth fluoride. The shells may be precisely deposited, due to the layer-wise deposition of atomic layer deposition methods, such that the relative composition of the coated component for semiconductor processing may be specified by repeating the operation 215 for a predetermined number of times. Furthermore, plasma removal of a native passivation layer 305 may improve control of surface chemistry and therefore improves the thermal, mechanical, and/or chemical properties of coated components for semiconductor processing.

As will be described further with regard to FIG. 4, the component for semiconductor processing may be, but is not limited to, a lid, a nozzle, a face plate, a gas distribution plate, a heater, a screw, a substrate support, a support platen, a liner, an edge ring, a process kit ring, or a lift pin. These components are commonly exposed to corrosive plasma conditions and may require corrosion-resistant and/or erosion-resistant coatings. By using coated components for semiconductor processing previously discussed, the corrosion-resistant and/or erosion-resistant material may be efficiently formed on the component and may provide desired corrosion and/or erosion resistance.

FIG. 4 show schematic views of an exemplary plasms processing system including one or more components formed by the method according to some embodiments of the present technology. FIG. 4 further illustrates details relating to a semiconductor processing system 400, and one or more components that may be incorporated into system 400 that may be or include a coated component for semiconductor processing. The coated component for semiconductor processing, in turn, may be formed by coating a component for semiconductor processing, such as the coated component for semiconductor processing prepared by the method 200. System 400 is understood to include any feature or aspect of a semiconductor processing chamber, and may be used to perform semiconductor processing operations including deposition, removal, and cleaning operations. System 400 may show a partial view of the chamber components being discussed and that may be incorporated in a typical semiconductor processing system, and may illustrate a view across a center of the pedestal and gas distributor, which may otherwise be of any size. Any aspect of system 400 may also be incorporated with other processing chambers or systems as will be readily understood by the skilled artisan.

System 400 may include a semiconductor processing chamber 450 including a showerhead 405, through which precursors 407 may be delivered for processing, and which may be configured to form a plasma 410 in a processing region between the showerhead 405 and a pedestal or substrate support 415. The showerhead 405 is shown at least partially internal to the chamber 450, and may be understood to be electrically isolated from the chamber 450. In this way, the showerhead 405 may act as a live electrode or as a reference ground electrode of a direct plasma system to expose a substrate held on the substrate support 415 to plasma generated species. The substrate support 415 may extend through the base of the chamber 450. The substrate support 415 may include a support platen 420, which may hold a semiconductor substrate 430 during deposition or removal processes used to form patterned structures on the semiconductor substrate 430.

The support platen 420 may be or include a coated component for semiconductor processing prepared in accordance with embodiments of method 200. The support platen 420 may incorporate embedded electrodes to provide the electrostatic field employed to hold the semiconductor substrate, and may also include a thermal control system that may facilitate processing operations including, but not limited to, deposition, etching, annealing, or desorption. In some embodiments, the support platen 420 may incorporate a plate, a perforated plate, a mesh, a wire screen, or any other distributed arrangement of conductive elements. The embedded electrodes may be or include a tuning electrode to provide further control over the plasma 410, for example, by adjusting an electric field near the surface of the support platen. Similarly, a bias electrode and/or an electrostatic chucking electrode, may be coupled with the support platen 420. The bias electrode may be coupled with a source of electric power, such as a DC power, pulsed DC power, RF bias power, a pulsed RF source or bias power, or a combination of these or other power sources. In this way, the substrate support 415 and the support platen 420 may be used during plasma processing operations not only to hold the semiconductor substrate 430, but also to tune the conditions of the plasma 410. Tuning the conditions of the plasma may include implementing automatic impedance matching to maintain plasma conditions during plasma processing operations, for example, while the composition of the plasma 410 is varied or as the surface of the semiconductor substrate 430 changes, for example, due to deposition of dielectric films onto electrode surfaces. In this way, precise control of the plasma 410 may depend on the material properties of the substrate support 415 and the support platen 420.

In some cases, the support platen 420 or other chamber components may be formed by coating a component for semiconductor processing with a layer of material 435. For example, a component for semiconductor processing may be treated for deposit a layer of material 435, such as a corrosion-resistant and/or erosion-resistant material. Prior and/or subsequent operations, such as annealing, machining, incorporating electrical components, may be applied to finish the component, providing a working component that can be incorporated in a plasma system. An advantage of using a coated component for semiconductor processing, for example, may include that a finished component with one or more layers of material 435 may serve as a refractory conductor, with favorable thermal deformation characteristics and chemical resistance to plasma etching, as well as electrical conductivity.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A processing method comprising:
providing a component for semiconductor processing to a processing region of a processing chamber;
providing one or more deposition precursors to the processing region, wherein the one or more deposition precursors comprise a metal-containing precursor and a fluorine-containing precursor; and
depositing a layer of material on the component for semiconductor processing in the processing region, wherein the layer of material comprises a metal-and-fluorine-containing material.

2. The processing method of claim 1, wherein the component for semiconductor processing comprises a ceramic-containing material.

3. The processing method of claim 2, wherein the ceramic-containing material comprises aluminum oxide (Al₂O₃), aluminum oxyfluoride (AlOₓF_{y}), yttrium oxide (Y₂O₃), yttrium oxyfluoride (YOₓF_{y}), magnesium oxide (MgO), magnesium oxyfluoride (MgOₓF_{y}), titanium oxide (TiO₂), titanium oxyfluoride (TiOₓF_{y}), aluminum nitride (AlN), aluminum oxynitride (AlOₓN_{y}), silicon nitride (Si₃N₄), or silicon oxynitride (SiOₓN_{y}).

4. The processing method of claim 1, wherein the metal-containing precursor comprises a hexafluoroacetylacetone compound.

5. The processing method of claim 1, wherein the metal-containing precursor comprises aluminum, calcium, erbium, lanthanum, magnesium, scandium, titanium, yttrium, or zirconium.

6. The processing method of claim 1, wherein the fluorine-containing precursor comprises hydrogen fluoride (HF), ammonium fluoride (NH4F) or ammonium bifluoride ([NH₄]F·HF).

7. The processing method of claim 1, wherein the layer of material comprises aluminum fluoride (AlF₃), aluminum oxyfluoride (AlOₓF_{y}), calcium fluoride (CaF₂), calcium oxyfluoride (CaOₓF_{y}), yttrium fluoride (YF₃), yttrium oxyfluoride (YOₓF_{y}), zirconium fluoride (ZrF₄), zirconium oxyfluoride (ZrOₓF_{y}), scandium fluoride (ScF₃), or scandium oxyfluoride (ScOₓF_{y}).

8. The processing method of claim 1, wherein the one or more deposition precursors further comprise an oxygen-containing precursor, and wherein the layer of material comprises a metal-fluorine-and-oxygen-containing material.

9. The processing method of claim 8, wherein the oxygen-containing precursor comprises steam (H₂O), molecular oxygen (O₂), ozone (O₃), nitrous oxide (N₂O), hydrogen peroxide (H₂O₂), an oxygen-containing plasma, or an alcohol-based plasma.

10. The processing method of claim 1, wherein the layer of material further comprises nitrogen.

11. The processing method of claim 1, further comprising:
generating plasma effluents of the one or more deposition precursors.

12. The processing method of claim 1, further comprising:
subsequent to depositing the layer of material, annealing the component for 2 semiconductor processing.

13. The processing method of claim 12, wherein the component for semiconductor processing is annealed in a pressure-controlled oxygen-containing environment, inert environment, or active gas environment.

14. The processing method of claim 1, wherein a temperature within the processing region is maintained at less than or about 2,000° C.

15. The processing method of claim 14, wherein the component for semiconductor processing comprises a lid, a nozzle, a face plate, a gas distribution plate, a heater, a screw, a substrate support, a support platen, a liner, an edge ring, a process kit ring, or a lift pin.

16. A processing method comprising:
providing a component for semiconductor processing to a processing region of a processing chamber;
depositing a layer of material on the component for semiconductor processing in the processing region, wherein the layer of material comprises a metal-and-fluorine-containing material, and wherein depositing the layer of material comprises:
exposing the component for semiconductor processing to plasma effluents of a first precursor;
purging the processing region; and
exposing the component for semiconductor processing to plasma effluents of a second precursor, wherein the layer of material comprises reaction products of the plasma effluents of the first precursor and the plasma effluents of the second precursor, and wherein a temperature within the processing chamber is maintained at greater than or about 400° C.

17. The processing method of claim 16, wherein the component for semiconductor processing comprises aluminum oxide (Al₂O₃), aluminum oxyfluoride (AlOₓF_{y}), yttrium oxide (Y₂O₃), yttrium oxyfluoride (YOₓF_{y}), magnesium oxide (MgO), magnesium oxyfluoride (MgOₓF_{y}), titanium oxide (TiO₂), titanium oxyfluoride (TiOₓF_{y}), aluminum nitride (AlN), aluminum oxynitride (AlOₓN_{y}), silicon nitride (Si₃N₄), or silicon oxynitride (SiOₓN_{y}).

18. The processing method of claim 16, wherein the layer of material comprises a metal-fluorine-and-oxygen-containing material.

19. A component for semiconductor processing comprising:
a ceramic component for semiconductor processing; and
a layer of metal-and-fluorine-containing material on the component for semiconductor processing, wherein:
the layer of metal-and-fluorine-containing material is formed on the ceramic component for semiconductor processing using a fluorine-containing precursor comprising ammonium fluoride (NH4F) or ammonium bifluoride ([NH₄]F·HF), a metal-containing precursor comprising a hexafluoroacetylacetone compound, or both;
a temperature while forming the layer of metal-and-fluorine-containing material on the component for semiconductor processing is maintained at greater than or about 400° C.; or
both.

20. The component for semiconductor processing of claim 19, wherein the component for semiconductor processing comprises a lid, a nozzle, a face plate, a gas distribution plate, a heater, a screw, a substrate support, a support platen, a liner, an edge ring, a process kit ring, or a lift pin.
